(19) United States
(12) Patent Application Publication
(10) Pub. No.: US 2022/0067602 A1
(43) Pub. Date: Mar. 3, 2022

(54) MANAGEMENT OF RISKS RELATED TO THE LACK OF COMPLIANCE WITH A DIMENSIONAL TOLERANCE IN A TOLERANCE CHAIN

(71) Applicant: Airbus Operations (S.A.S.), Toulouse (FR)

(72) Inventors: Ambre Diet, Toulouse (FR); Julien Martin, Toulouse (FR); Jean-Philippe Navarro, Toulouse (FR)

(21) Appl. No.: 17/459,232

(22) Filed: Aug. 27, 2021

(30) Foreign Application Priority Data
Aug. 31, 2020 (FR) 2008847

(51) Int. Cl. G06Q 10/06; G06Q 30/00

(52) U.S. Cl. CPC G06Q 10/0635; G06Q 30/018

(57) ABSTRACT

A tool, method and system for automatically managing risks including a processor configured to select an input characteristic, called a target characteristic, the contribution of which in the tolerance chain is greater than a predetermined contribution threshold, replace the value of the target characteristic with a test value, determine an output statistical distribution according to each test value, measure the portion of lack of compliance with the tolerances that are associated with the output requirements, evaluate a first indicator of the impact of the risk of lack of compliance with tolerances associated with the output requirements according to each test value, evaluate a second indicator of severity of the risk representing weighting of the first indicator of the impact of the risk with a probability of occurrence of the test value, and define a set of sorting criteria which are graduated on the basis of the first and second indicators.

### CROSS-REFERENCE TO RELATED APPLICATION

This application claims priority to French patent application number 20 08847 filed on Aug. 31, 2020, the entire disclosure of which is incorporated by reference herein.

### TECHNICAL FIELD

The disclosure herein relates to the general field of assembling subassemblies of a vehicle and, more particularly, to the management of risks related to the lack of compliance with at least one dimensional tolerance in a tolerance chain used in the assembly of a set of parts corresponding to at least part of a vehicle.

### BACKGROUND

When a vehicle is designed, it is sought to define the dimensions of the various parts to be assembled and acceptable tolerances which ensure a precise fit between these parts. The tolerances are generally defined before the start of production phases, in a conservative approach.

The conservative approach generally uses a technique for defining tolerances of “worst-case” type which is based on the condition of maintaining the required output tolerance for any combination of actual dimensions of the elements. This ensures high precision.

Thus, if all of the tolerances are observed, the outcome of assembly will be satisfactory. However, the inverse is not true. Specifically, the outcome of assembly may also be good despite not all of the tolerances being observed.

The current technique generally covers the phase of defining the tolerances but does not cover reviewing or estimating risks when the tolerances are not observed.

Specifically, it is not at all straightforward to predict the risk for this or that assembly of parts, hence the resorting to a conservative approach which ensures high precision but which at the same time may generate a great deal of waste and delays in the manufacture of the final product.

The object of the disclosure herein is therefore to provide an automatic method for managing the risk related to the lack of compliance with one of the tolerances while ensuring the absence of impact on the performance, safety and reliability of the final product.

### SUMMARY

The disclosure herein relates to an automatic risk management tool for managing risks related to the lack of compliance with at least one dimensional tolerance in a tolerance chain in the context of industrially assembling a product from a set of parts, the tolerance chain being defined by a tolerance model relating input characteristic values representative of the tolerances of the parts to be assembled to output requirement values representative of the requirements for the assembled parts, the input characteristic values and the output requirement values being associated with input tolerances and output tolerances, respectively, the tool comprising a processor configured to:
select an input characteristic, called a target characteristic, the contribution of which in the tolerance chain is greater than a predetermined contribution threshold,
replace the value of the target characteristic with a test value from among a series of test values that are representative of potential measurement values,
determine the output statistical distribution associated with each test value assigned to the target characteristic thus forming a set of output statistical distributions,
measure the portion of lack of compliance with the tolerances that are associated with the output requirements for each output statistical distribution,
evaluate a first indicator of the impact of the risk of lack of compliance with the tolerances that are associated with the output requirements according to each test value assigned to the target characteristic,
evaluate a second indicator of the severity of the risk representing the weighting of the first indicator of the impact of the risk with a probability of occurrence of the corresponding test value assigned to the target characteristic, and
define a set of sorting criteria which is graduated on the basis of the first and second indicators.

It is noted that multiple test values are tested in order to simulate various measurements and then the risk curve is established by postprocessing the collection of output distributions obtained.

This tool makes it possible to automatically manage the physical elements beyond geometric tolerances in relation to a definition file while ensuring that there will be no impact on performance, safety, manufacturability or any function performed by the final product. The tool makes it possible to select optimal parts with a view to guaranteeing all of the final requirements while being robust and economically advantageous.

Advantageously, the first indicator of the impact of the risk corresponds to a conditional probability of not complying with the tolerances that are associated with the output requirements knowing that a given test value (representative of a potential measurement value) has been assigned to the target characteristic.

This makes it possible to evaluate the impact of the risk of a part beyond tolerance.

Advantageously, the second indicator of the severity of the risk corresponds to the combined probability of obtaining the given test value and of not complying with the tolerances associated with the output requirements, the second indicator of the severity of the risk thus corresponding to the product of the first indicator of the impact with the probability of occurrence of the given test value.

This makes it possible to more precisely evaluate the impact of the risk of a part that is not compliant with the predefined tolerances by taking account of the probability of occurrence of this lack of conformity with the predefined tolerances.

Advantageously, the definition of the set of decision-making criteria comprises: a first criterion according to which a part is accepted as it is without taking any particular action, a second criterion according to which the part is accepted as it is while requiring additional inspections at a later stage, a third criterion according to which the part is to be repaired, and a fourth criterion according to which the part is to be remade.

This makes it possible to adapt the criteria for accepting a part to what is actually needed in the industrial context at that time and minimize repairs or potential remaking of parts that are not compliant.

Advantageously, the processor is configured to determine the parts that are able to be assembled together by sorting the parts according to the various sorting criteria.

Advantageously, the test value is represented by a statistical distribution of Gaussian distribution type centered on the test value or a Dirac distribution.

Thus, the distribution of the test value is adapted to the observed measurement data and according to the lack of precision of the measurement.

Advantageously, the determination of the output statistical distribution relating to each test value is performed by a statistical calculation of convolution product type of the input characteristic values, or by a numerical approximation technique of Monte-Carlo simulation type.

This makes it possible to precisely correlate the output statistical distribution with the input data.

Advantageously, the tolerance model is fed, in a prior training phase, with statistical data stemming from the feedback of actual measurements on the parts to be assembled.

Thus, the actual input-output measurements constitute a training dataset on the basis of which the tolerance model is calibrated.

Advantageously, the tolerance model is validated beforehand.

Thus, validation of the tolerance model makes it possible to guarantee the prediction effectiveness of the model.

According to one embodiment, the tolerance model expresses an output requirement Y according to a linear combination of the input requirements Xᵢ in the following manner:

Y=Σᵢ₌₁^{N}αᵢ·Xᵢ

where αᵢ is a coefficient of influence of geometric origin, and N represents the number of links in the tolerance chain.

According to one embodiment, the predetermined contribution threshold is equal to 20% of the worst-case sum of the links in the chain.

The disclosure herein also targets a system for industrially assembling a product from a set of parts, some of which parts might not be compliant with geometric tolerances, comprising:
an automatic risk management tool according to any one of the preceding features, the management tool being capable of sorting the parts to be assembled according to first, second, third and fourth sorting criteria, the first and second sorting criteria defining those parts which are able to be assembled together without any risk, and
assembly tools capable of assembling only those parts which satisfy the first and second sorting criteria even though some of the parts might not be compliant with geometric tolerances.

The disclosure herein also targets a method for using the risk management tool according to any one of the preceding features to assemble a set of parts, comprising the following steps:
taking the dimensions of a part,
testing whether the measurements are compliant with the dimensional tolerance values, if so, the part is accepted, if not, the method moves on to the next step,
collecting the input characteristics relating to the part,
entering the input characteristics into the tolerance model in order to obtain the set of graduated decision-making criteria,
testing whether the part meets the first criterion, if so, it is accepted as it is without taking any particular action, if not, the method moves on to the next step,
testing whether the part meets the second criterion, if so, it is accepted as it is while requiring additional inspections at a later stage, if not, the method moves on to the next step,
testing whether the part meets the third criterion, if so, the part has to be repaired, if not, the method moves on to the next step, and
testing whether the part meets the fourth criterion, if so, the part has to be remade.

Advantageously, the set of parts corresponds to at least part of an aircraft.

Advantageously, the set of parts may be a set of elementary parts or a set of objects from among the following objects: fuselage sections, vertical stabilizers, flight surfaces, passenger doors, cargo doors, engines, nacelles, engine pylons, horizontal and vertical planes, landing gears, cabin elements or other parts of the aircraft.

Further advantages and features of the disclosure herein will become apparent from the following non-limiting detailed description.

### BRIEF DESCRIPTION OF THE DRAWINGS

Some embodiments of the disclosure herein will now be described, by way of non-limiting examples, and with reference to the appended drawings, in which:

FIG. 1 schematically illustrates an automatic risk management tool for managing risks related to the lack of compliance with at least one dimensional tolerance in a tolerance chain according to one embodiment of the disclosure herein;

FIG. 2 is a flow chart schematically illustrating steps performed by an automatic risk management tool for managing risks related to the lack of compliance with at least one dimensional tolerance according to one embodiment of the disclosure herein;

FIG. 3 is a graph illustrating a risk chart represented by a set of curves plotting variations in risk impacts according to one embodiment of the disclosure herein;

FIG. 4 is a flowchart schematically illustrating steps of a method for using the risk management tool according to one embodiment of the disclosure herein; and

FIG. 5 schematically illustrates an assembly system using the risk management tool according to one embodiment of the disclosure herein.

### DETAILED DESCRIPTION

A concept underlying the disclosure herein is that of taking advantage of a feedback of measurement data in production to manage risks a posteriori related to the lack of compliance with one or more dimensional tolerances in a tolerance chain.

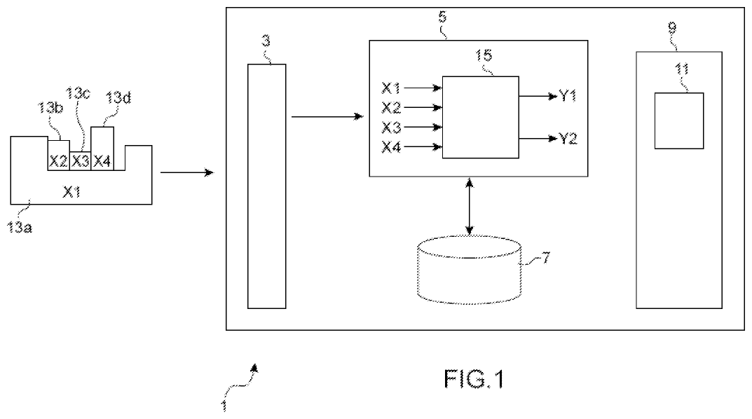

FIG. 1 schematically illustrates an automatic risk management system or tool for managing risks related to the lack of compliance with at least one dimensional tolerance in a tolerance chain according to one embodiment of the disclosure herein.

This tool 1 comprises input interfaces 3, a processor for processing data 5, memories and/or servers for storing data 7, and output interfaces 9 comprising a graphical interface 11.

According to the disclosure herein, the tool 1 is designed to automatically manage risks related to the lack of compliance with at least one dimensional tolerance X in a tolerance chain in the context of industrially assembling a product from a set of parts 13a-13d.

By way of example, the product may correspond to at least part of an aircraft and, more particularly, to flight surface and fuselage sections of an aircraft.

What is meant by “set of parts” 13a-13d is a set of partial components, each of which may be a subassembly of more elementary parts. For example, an aircraft may be considered as being composed of a plurality of parts or elements which comprise, non-exhaustively: an airframe, a power plant, flight controls, on-board utilities, an avionics system, and internal or external payloads. Each of these elements is itself a subassembly composed of more elementary parts. For example, the airframe comprises a fuselage, flight surfaces, empennage and a landing gear. Furthermore, each element of the subassembly is in turn composed of other elements and so on. For example, the flight surfaces comprise two wings, ailerons, and tail parts. Furthermore, the internal structure of each wing comprises spars and ribs, etc.

The assembly of a set of parts 13a-13d requires the prior determination of a dimensional tolerance chain corresponding to this set. The tolerance chain is defined by a tolerance model 15 relating input characteristic values Xi (for example, X1-X4) to output requirement values Yj (Y1, Y2). The input characteristic values and the output requirement values are associated with input tolerances and output tolerances, respectively.

A tolerance model, in its simplest, linear version, relates an output requirement Y to input characteristic values Xi through the following formula:

Y=Σᵢ₌₁^{N}αᵢ·Xᵢ (1)

The input tolerances associated with the input characteristic values Xi represent the tolerances for the parts 13a-13d or elements to be assembled together. The output tolerances represent the requirements for the assembled parts 13a-13d. The coefficient αᵢ is a linear influence parameter of geometric origin, and N denotes the number of elements in the assembly chain. It is noted that the coefficient αᵢ of influence of the tolerance of an element on the output Y may be equal to +1 or −1 in the context of a one-dimensional, 1D, tolerance chain, and may be equal to any value in the case of a 2D or 3D tolerance chain.

According to the disclosure herein, the processor 5, in association with the data storage servers 7, implements a training algorithm to construct the tolerance model.

In a prior training phase, the tolerance model 15 is fed with a body of statistical data stored in the data storage servers 7 and stemming from the feedback of actual measurements on the elements or parts to be assembled, no matter their defined tolerances. Thus, the actual input-output measurements constitute a training dataset. The processor 5 uses a first portion of the training dataset to calibrate the tolerance model 15 so that this model automatically learns to predict the output data from new input data. By way of example, the tolerance model 15 may exhibit a conservative tolerance definition approach of “worst-case” type.

The parameters taken into account in the training dataset are, in particular, the type of statistical distribution representing the population, its dispersion (for example, the standard deviation for a Gaussian distribution), and its position (for example, the mean for a Gaussian distribution). Those links which are not measured are replaced with a conservative distribution using the defined parameters of the tolerances. By way of example, it is possible to use a uniform distribution between the defined limits of the tolerances.

Advantageously, the processor 5 uses a second portion of the training dataset to test and validate the tolerance model 15, thereby guaranteeing its prediction effectiveness. For example, this may be achieved using a supervised learning technique so that known output data variations are properly explained on the basis of input data variations.

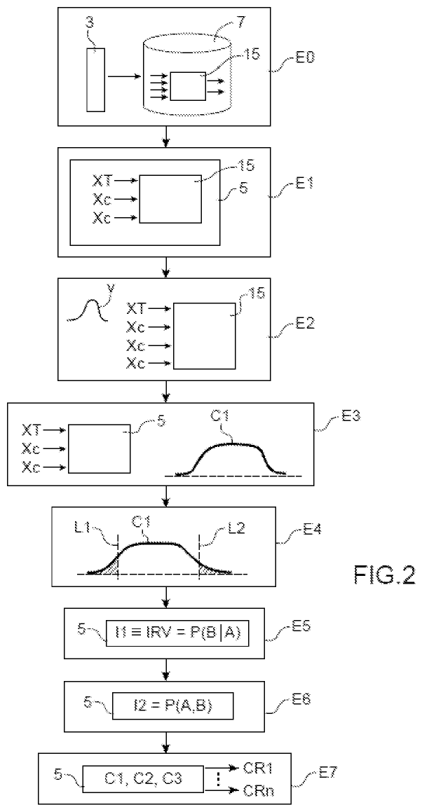

FIG. 2 is a flow chart schematically illustrating steps performed by an automatic risk management tool for managing risks related to the lack of compliance with at least one dimensional tolerance according to one embodiment of the disclosure herein.

Initially, in step E0, the initialization and input data relating to the tolerance model are stored in the memories 7 of the system 1 via the input interfaces 3. Thus, the tolerance model 15 relating input characteristic values to output requirement values defining the tolerance chain is stored in the memories 7 of the tool 1.

In step E1, the processor 5 is configured to select an input characteristic, called a target characteristic XT (i.e. one of the links in the tolerance chain), the contribution of which in the tolerance chain is greater than a predetermined contribution threshold. By way of example, the predetermined contribution threshold is equal to 20% of the worst-case sum of the links in the chain.

Additionally, the other input characteristics are considered to be contributing characteristics Xc according to usual capabilities.

In step E2, the processor 5 is configured to replace the value of the target characteristic XT with a test value V from among a series of test values that are representative of potential possible measurement values.

The test value V is expressed by a statistical distribution representative of the observed measurement data and their potential lack of precision. It may be a Gaussian distribution centered on the test value taking into account the dispersion of the measurement according to the assumed capability of this measurement. The test value may also be expressed by a Dirac distribution representing an observed measurement value without dispersion. It may also be expressed by other types of distribution such as, for example, a uniform distribution.

In step E3, the processor 5 is configured to determine an output statistical distribution C1 according to each test value V assigned to the target characteristic XT thus forming a set of output statistical distributions.

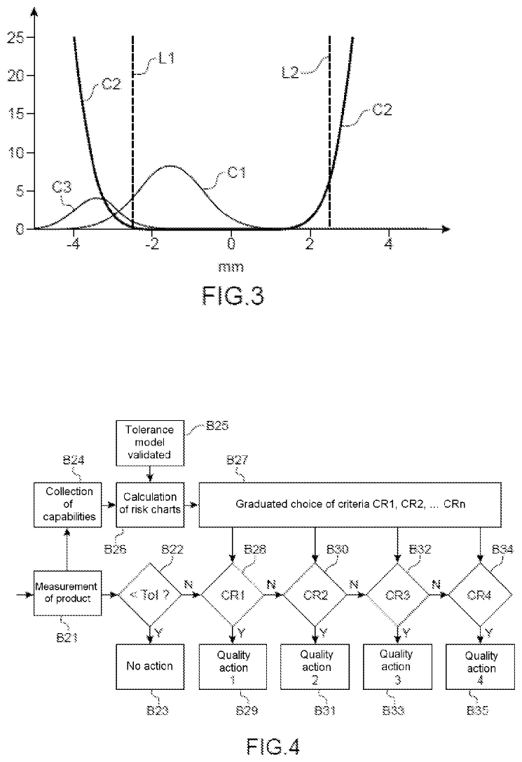

By way of example, the processor 5 is configured to determine the output statistical distribution relating to each test value V by using a statistical calculation of convolution product type of the input characteristic values. Specifically, the convolution product of the distributions generates a link between the input data and the output data which may be represented by a normalized output curve C1 (also see FIG. 3).

It is noted that the output statistical distribution may be determined by other techniques such as, for example, the numerical approximation method of Monte-Carlo simulation type.

In step E4, the processor 5 is configured to measure the portion of lack of compliance with the tolerances that are associated with the output requirements for each output statistical distribution. The portion of lack of compliance with the tolerances corresponds to the area (beneath the normalized output curve C1) that exceeds the predetermined tolerance limits L1 and L2. This indicates those output requirements which are affected by lack of compliance with the tolerances.

Steps E2-E4 are launched multiple times iteratively with an incremental variation in the test value V. This iterative process makes it possible to determine the variation in the risk of lack of compliance with the tolerances knowing that the target characteristic V has been measured at a specific value vs.

In step E5, the processor 5 is configured to evaluate a first indicator I1 of the impact of the risk of lack of compliance with the tolerances that are associated with the output requirements according to each test value V assigned to the target characteristic XT. For a given input measurement, the first impact indicator I1 is denoted “ERI” (evaluated risk impact) hereinafter.

This first indicator of the impact of the risk ERI corresponds to a conditional probability of not complying with the tolerances that are associated with the output requirements knowing that a given test value (representative of a potential specific measurement value) has been assigned to the target characteristic. Specifically, if the terms “the target characteristic has been measured at the specific value vₐ” are denoted by the event “A” and the terms “the output requirements do not comply with the output tolerances” are denoted by the event “B”, then the first indicator of the impact of the risk is defined by the conditional probability P(B|A) of event B in the knowledge of event A.

Thus, the value ERI of a given measurement corresponds to the value of the conditional probability P(B|A) which may be expressed as a percentage. Still, it is advantageous to weight this evaluation of the impact of the lack of compliance with the tolerance with a probability of occurrence which, in this case, corresponds to the statistical distribution followed by the population of the target characteristic.

Specifically, in step E6, the processor 5 is configured to evaluate a second indicator I2 of the severity of the risk representing the weighting of the first indicator 11 of the impact of the risk with a probability of occurrence of the corresponding test value assigned to the target characteristic.

This second indicator I2 of the severity of the risk is a weighted risk which corresponds to the combined probability of obtaining the given test value (i.e. event A) AND of not complying with the tolerances associated with the output requirements (i.e. event B). Thus, the second indicator I2 of the severity of the risk corresponds to the probability P(A,B) of event A AND of event B. This probability P(A,B) then corresponds to the product of the first, impact indicator (i.e. P(B|A)) with the probability of occurrence of the given test value (i.e. P(A)) which is expressed by the Bayes probability formula below:

P(A,B)=P(B|A)·P(A) (2)

The set of indicators determined in the preceding steps may be represented by curves on the graphical interface 11 of the system 1.

Specifically, FIG. 3 is a graph illustrating a risk chart represented by a set of curves plotting variations in risk impacts according to one embodiment of the disclosure herein.

The y-axis of the graph represents the amplitude of the distribution and the x-axis represents the tolerance in millimetres. The two dashed vertical lines L1, L2 represent the tolerance range defined for the target characteristic XT.

Curve C1 is a distribution of a test value assigned to the target characteristic XT representative of observed measurement data and their lack of precision.

Curve C2 is a U-shaped curve representing the first, impact indicator I1 indicating the risk of the requirement not being observed according to the measured value of the target characteristic XT.

Curve C3 represents the second indicator I2 of the severity of the risk defining the risk weighted by the probability of occurrence of the value assigned to the target characteristic XT. More particularly, the integral beneath curve C3, between two given limits, makes it possible to quantify the risk of incorrect acceptance with respect to an occurrence of the target characteristic XT. This value, denoted hereinafter by “WIR” (weighted integrator risk), indicates the severity of the risk as a percentage.

The set of curves C1-C3 thus obtained represent risk charts and support the decision for extended acceptance criteria where the risk remains insignificant. Specifically, in step E7, the processor 5 is configured to define a set of acceptance or sorting criteria CR₁-CRₙ which are graduated on the basis of the first and second indicators (or risk chart C1-C3).

By way of example, it is possible to define four sorting criteria for ERI values between 0% and 20% and WIR values between 0% and 3%. These data are experimental target values. They are dependent on the risk that can be tolerated by the industrial system and may be refined for each factory, or even for each characteristic depending on the criticality thereof.

The set of sorting criteria comprises: a first criterion CR₁ according to which a part is accepted as it is without taking any particular action, a second criterion CR₂ according to which the part is accepted as it is while requiring additional inspections at a later stage, a third criterion CR₃ according to which the part is to be repaired, and a fourth criterion CR₄ according to which the part is to be remade.

This automatic risk management tool may be applied on a very large scale in order to monitor the variations in capabilities of the input characteristics. The characteristics validated by this tool may follow a simple and economically advantageous process for monitoring for quality non-compliance.

The sorting criteria validated by this tool may have a finite lifespan since the capabilities used in the management tool are liable to gradually change. A notification mechanism informing users or automatically reviewing these criteria may be implemented in order to increase the application lifespan.

It is noted that in the embodiment of the management tool according to FIG. 2, usual capabilities have been used for the distributions that are associated with the contributing characteristics (i.e. the input characteristics other than the target characteristic).

As a variant, it is possible to take into account, for the distributions associated with the contributing characteristics, measurements which have potentially already been taken instead of their usual capabilities, while ensuring that the pairing of the different instances of the characteristics in question is properly associated with the assembly instance. In this case, the acceptance criteria will be different for each assembly instance. This alternative also makes it possible to select those physical elements which have the greatest likelihood of being assembled together if a comparison between multiple alternatives for pairing of the parts is made on the basis of the ERI values.

Advantageously, the graphical interface 11 of the system 1 reports the result of the calculations to the users and may be combined with any process for managing quality non-compliance in its capacity as a tool for assessing the risks related to the lack of compliance with intermediate geometric tolerances.

FIG. 4 is a flowchart schematically illustrating a method for using the risk management tool to sort the parts to be assembled according to one embodiment of the disclosure herein.

In box B21, the management tool 1 collects measurements relating to the dimensions of a part. The part may be an element from a set of elementary parts corresponding to at least part of an aircraft. This set may comprise elements from among the following objects: fuselage sections, vertical stabilizers, flight surfaces, passenger doors, cargo doors, engines, nacelles, engine pylons, horizontal and vertical planes, landing gears, cabin elements or other parts of the aircraft.

In box B22, the management tool 1 tests whether these measurements are compliant with the dimensional tolerance values “Tol”.

If so (i.e. if the measurements are compliant), the part is accepted in box B23 with no further action; if not, the method moves on to the next step.

In box B24, the management tool collects the capabilities of the input characteristics relating to the part, thus forming the input data for the tolerance model.

In box B25, on the basis of the output data from the tolerance model (box B26), the management tool generates the risk charts which may be displayed on the graphical interface 11.

In box B27, the management tool generates a graduated choice of the sorting criteria CR₁, . . . , CRₙ. By way of example, four sorting criteria CR₁, . . . , CR₄ are considered hereinafter.

In box B28, the management tool tests whether the part meets the first criterion CR₁; if so, the part is accepted as it is (box B29) without taking any particular action; if not, the method moves on to the next box.

In box B30, the management tool tests whether the part meets the second criterion CR₂. If so, the part is accepted as it is while requiring additional inspections at a later stage (box B31); if not, the method moves on to the next box.

In box B32, the management tool tests whether the part meets the third criterion CR₃. If so, the part has to be repaired (box B33); if not, the method moves on to the next box.

In box B34, the management tool tests whether the part meets the fourth criterion CR₄. If so, the part has to be remade (box B35).

Thus, the management tool makes it possible to sort the parts to be assembled according to the various sorting criteria, thereby determining the parts that are able to be assembled together.

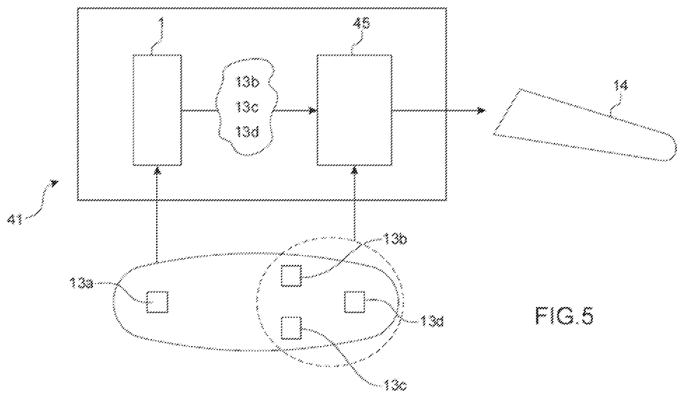

FIG. 5 schematically illustrates an industrial assembly system using the risk management tool according to one embodiment of the disclosure herein.

The industrial assembly system 41 comprises the automatic risk management tool 1 described with reference to FIGS. 1 and 2 and industrial assembly tools 45.

According to one embodiment of the disclosure herein, the industrial assembly system 41 is intended to assemble a final product 14 from a set of parts 13a-13d, some of which parts might not be compliant with geometric tolerances.

As described above, the risk management tool 1 is capable of sorting the parts to be assembled according to first, second, third and fourth sorting criteria. The processor 5 is configured to determine the parts that are able to be assembled together by sorting the parts according to the various sorting criteria. More particularly, the first and second sorting criteria define those parts which may be assembled together without any risk.

By way of example, FIG. 5 shows that only parts 13b-13d are suitable for being assembled while part 13a has to be remade.

Furthermore, the assembly tools 45 are capable of assembling only those parts 13b-13d which satisfy the first and second sorting criteria even though some of the parts might not be compliant with geometric tolerances.

The assembly system thus makes it possible to sort the parts and to assemble those which will not have any impact on the performance of the final product even if some of them exhibit non-compliant geometric tolerances.

The disclosure herein makes it possible to accept certain geometric tolerance elements which are not compliant with the definition file while ensuring that there will be no impact on performance, safety, manufacturability or any function performed by the final product. Furthermore, the disclosure herein makes it possible to select and assemble optimal part combinations with a view to guaranteeing all of the requirements of the final product. Additionally, the disclosure herein makes it possible to adapt the criteria for accepting a part to what is actually needed in the industrial context at that time and minimize repairs or potential remaking of parts that are not compliant.

The subject matter disclosed herein can be implemented in or with software in combination with hardware and/or firmware. For example, the subject matter described herein can be implemented in software executed by a processor or processing unit. In one example implementation, the subject matter described herein can be implemented using a computer readable medium having stored thereon computer executable instructions that when executed by a processor of a computer control the computer to perform steps. Example computer readable mediums suitable for implementing the subject matter described herein include non-transitory devices, such as disk memory devices, chip memory devices, programmable logic devices, and application specific integrated circuits. In addition, a computer readable medium that implements the subject matter described herein can be located on a single device or computing platform or can be distributed across multiple devices or computing platforms.

While at least one example embodiment of the invention(s) is disclosed herein, it should be understood that modifications, substitutions and alternatives may be apparent to one of ordinary skill in the art and can be made without departing from the scope of this disclosure. This disclosure is intended to cover any adaptations or variations of the example embodiment(s). In addition, in this disclosure, the terms “comprise” or “comprising” do not exclude other elements or steps, the terms “a”, “an” or “one” do not exclude a plural number, and the term “or” means either or both. Furthermore, characteristics or steps which have been described may also be used in combination with other characteristics or steps and in any order unless the disclosure or context suggests otherwise. This disclosure hereby incorporates by reference the complete disclosure of any patent or application from which it claims benefit or priority.

1. An automatic risk management tool for managing risks related to lack of compliance with at least one dimensional tolerance in a tolerance chain in context of industrially assembling a product from a set of parts, the tolerance chain being defined by a tolerance model relating input characteristic values representative of tolerances of the parts to be assembled to output requirement values representative of requirements for the assembled parts, the input characteristic values and the output requirement values being associated with input tolerances and output tolerances, respectively, the tool comprising a processor configured to:
select an input characteristic, which is a target characteristic, a contribution of which in the tolerance chain is greater than a predetermined contribution threshold;
replace a value of the target characteristic with a test value from among a series of test values that are representative of potential measurement values;
determine an output statistical distribution according to each test value assigned to the target characteristic thus forming a set of output statistical distributions;
measure a portion of lack of compliance with the tolerances associated with the output requirements for each output statistical distribution;
evaluate a first indicator of an impact of risk of lack of compliance with the tolerances that are associated with the output requirements according to each test value assigned to the target characteristic;
evaluate a second indicator of a severity of risk representing a weighting of the first indicator of the impact of the risk with a probability of occurrence of a corresponding test value assigned to the target characteristic; and
define a set of sorting criteria which is graduated on a basis of the first indicator and the second indicator.

2. The tool according to claim 1, where the first indicator of the impact of the risk corresponds to a conditional probability of not complying with the tolerances that are associated with the output requirements where a given test value has been assigned to the target characteristic.

3. The tool according to claim 1, where the second indicator of the severity of the risk corresponds to a combined probability of obtaining a given test value and of not complying with the tolerances associated with the output requirements, the second indicator of the severity of the risk thus corresponding to a product of the first indicator of the impact with the probability of occurrence of the given test value.

4. The tool according to claim 1, where a definition of a set of decision-making criteria comprises: a first criterion according to which a part is accepted as it is without taking any particular action, a second criterion according to which the part is accepted as it is while requiring additional inspections at a later stage, a third criterion according to which the part is to be repaired, and a fourth criterion according to which the part is to be remade.

5. The tool according to claim 1, where the processor is configured to determine the parts that are able to be assembled together by sorting the parts according to various sorting criteria.

6. The tool according to claim 1, where the test value is represented by a statistical distribution of Gaussian distribution type centered on the test value or a Dirac distribution.

7. The tool according to claim 1, where determining the output statistical distribution relating to each test value comprises a statistical calculation of convolution product type of the input characteristic values, or by a numerical approximation technique of Monte-Carlo simulation type.

8. The tool according to claim 1, where the tolerance model is fed, in a prior training phase, with statistical data stemming from feedback of actual measurements on the parts to be assembled.

9. The tool according to claim 1, where the tolerance model is validated beforehand.

10. The tool according to claim 1, where the tolerance model expresses an output requirement Y according to a linear combination of the input requirements Xᵢ in a following manner:
Y=Σᵢ₌₁^{N}αᵢ·Xᵢ
where αᵢ is a coefficient of influence of geometric origin, and N represents a number of links in the tolerance chain.

11. The tool according to claim 1, where the predetermined contribution threshold is equal to 20% of a worst-case sum of links in the chain.

12. A system for industrially assembling a product from a set of parts, some of which parts might not be compliant with geometric tolerances, the system comprising:
an automatic risk management tool according to claim 1, the management tool configured for sorting the parts to be assembled according to first, second, third and fourth sorting criteria, the first and second sorting criteria defining those parts which are able to be assembled together without any risk; and
assembly tools configured for assembling only those parts which satisfy the first and second sorting criteria even though some of the parts might not be compliant with geometric tolerances.

13. An assembly method using the risk management tool according to claim 1 to assemble a set of parts, the method comprising:
taking measurements relating to dimensions of a part;
testing whether the measurements are compliant with the dimensional tolerance values, and if so, the part is accepted, and if not, the method moves on to a next step;
collecting the input characteristics relating to the part;
entering the input characteristics into the tolerance model to obtain a set of graduated decision-making criteria;
testing whether the part meets a first criterion, and if so, it is accepted as it is without taking any particular action, and if not, the method moves on to a next step;
testing whether the part meets a second criterion, and if so, it is accepted as it is while requiring additional inspections at a later stage, and if not, the method moves on to a next step;
testing whether the part meets a third criterion, and if so, the part has to be repaired, and if not, the method moves on to a next step; and
testing whether the part meets a fourth criterion, and if so, the part has to be remade.

14. The method according to claim 13, where the set of parts corresponds to at least part of an aircraft.

15. The method according to claim 14, where the set of parts comprises a set of elementary parts or a set of objects from among the group selected from fuselage sections, vertical stabilizers, flight surfaces, passenger doors, cargo doors, engines, nacelles, engine pylons, horizontal and vertical planes, landing gears, cabin elements and other parts of the aircraft.
